(19) United States
(12) Patent Application Publication
(10) Pub. No.: US 2026/0282831 A1
(43) Pub. Date: Sep. 17, 2026

(54) ELECTROSTATIC CHUCK

(71) Applicant: TOTO LTD., Fukuoka (JP)

(72) Inventors: Yohei UENO, Fukuoka (JP); Yuki OSAKABE, Fukuoka (JP); Masafumi IKEGUCHI, Fukuoka (JP); Tomoki UMETSU, Fukuoka (JP); Tatsuya MORI, Fukuoka (JP); Keigo UMEZAWA, Fukuoka (JP)

(73) Assignee: TOTO LTD., Fukuoka (JP)

(21) Appl. No.: 19/542,286

(22) Filed: Feb. 17, 2026

(30) Foreign Application Priority Data
Mar. 14, 2025 (JP) 2025-041381

(51) Int. Cl. H10P 72/72; H01J 37/32

(52) U.S. Cl. CPC H10P 72/722; H01J 37/32724; H01J 2237/334

(57) ABSTRACT

An electrostatic chuck 10 includes a dielectric substrate 100, and a heater unit 300 that heats the dielectric substrate 100. The heater unit 300 includes a heat generation layer that generates heat by receiving electric power supplied from outside, an insulating layer 320 that accommodates the heat generation layer inside, a first conductor plate 310A that is arranged so as to be in contact with the insulating layer 320 from the dielectric substrate 100 side, and a second conductor plate 310B that is arranged so as to be in contact with the insulating layer 320 from a side opposite to the dielectric substrate 100. A through hole 304 is formed in the heater unit 300. In the electrostatic chuck 10, a diameter D2 of the through hole 304 formed in the second conductor plate 310B is larger than a diameter D3 of the through hole 304 formed in the insulating layer 320.

### CROSS-REFERENCE TO RELATED APPLICATION

This application is based upon and claims the benefit of priority from Japanese Patent Application No. 2025-041381 filed on Mar. 14, 2025, the entire contents of which are incorporated herein by reference.

### FIELD

The present invention relates to an electrostatic chuck.

### BACKGROUND

For example, in a semiconductor manufacturing apparatus including an etching apparatus, an electrostatic chuck is provided as an apparatus configured to attract and hold a wafer such as a silicon wafer to be processed. The electrostatic chuck includes a dielectric substrate to which an attraction electrode is provided and a base plate which supports the dielectric substrate. When a voltage is applied to the attraction electrode, an electrostatic force is generated, and the wafer placed on the dielectric substrate is attracted and held.

During a process on the wafer, an in-plane temperature distribution of the wafer is required to be as uniform as possible. To enable the in-plane temperature distribution of the wafer to be regulated with high accuracy, an electrostatic chuck including a heater has been developed in recent years, which has already been put to practical use. The heater may be provided inside the dielectric substrate, or may be provided as a heater unit between the dielectric substrate and the base plate as disclosed in, for example, Japanese Patent Laid-open No. 2021-197485.

### SUMMARY

The inventors have been studying a configuration of a heater unit for heating a dielectric substrate, the configuration including an insulating layer that accommodates a heat generation layer inside, and a pair of conductor plates that vertically sandwich the insulating layer.

In the heater unit, it is necessary to form through holes that penetrate the entire heater unit, for example, as lift pin holes and gas supply holes. In the heater unit having the above-described configuration, insulation breakdown may occur inside the through holes along a path that extends from one of the conductor plates to the other conductor plate.

The present invention has been made in view of such a problem, and aims at providing an electrostatic chuck that can suppress insulation breakdown in through holes of a heater unit.

To solve the above-described problem, an electrostatic chuck according to the present invention includes a dielectric substrate including a placement surface on which an object to be attracted is placed, and a heater unit that is joined to the dielectric substrate and heats the dielectric substrate. The heater unit includes a heat generation layer that generates heat by receiving electric power supplied from outside, an insulating layer that accommodates the heat generation layer inside, a first conductor plate that is arranged so as to be in contact with the insulating layer from the dielectric substrate side, and a second conductor plate that is arranged so as to be in contact with the insulating layer from a side opposite to the dielectric substrate. A through hole that penetrates the entire heater unit in a direction vertical to the placement surface is formed in the heater unit. In the electrostatic chuck, a diameter of the through hole formed in the second conductor plate is larger than a diameter of the through hole formed in the insulating layer.

In the electrostatic chuck having the above-described configuration, a portion of the insulating layer projects so as to obstruct, in the middle, a path that extends from an edge of the through hole formed in the first conductor plate to an edge of the through hole formed in the second conductor plate. Inside the through hole, insulation breakdown from the first conductor plate to the second conductor plate can occur only along a path that bypasses the projecting insulating layer, and thus occurrence of such insulation breakdown can be suppressed.

According to the present invention, it is possible to provide an electrostatic chuck that can suppress insulation breakdown in through holes of a heater unit.

### BRIEF DESCRIPTION OF THE DRAWINGS

FIG. 1 is a cross-sectional view schematically illustrating a configuration of an electrostatic chuck according to a first embodiment;

FIG. 2 is an exploded view schematically illustrating a configuration of a heater unit;

FIG. 3 is a diagram illustrating an example of arrangement of sub-heater layers in the heater unit;

FIG. 4 is a diagram illustrating a configuration of one sub-heater layer;

FIG. 5 is a diagram illustrating an example of arrangement of main heater layers in the heater unit;

FIG. 6 is a diagram illustrating a configuration of one main heater layer;

FIG. 7 is a diagram for explaining a role of a bypass layer and the like;

FIG. 8 is a cross-sectional view schematically illustrating a configuration of a portion of the heater unit according to the first embodiment;

FIG. 9 is a cross-sectional view schematically illustrating a configuration of a portion of a heater unit according to a second embodiment; and

FIG. 10 is a cross-sectional view schematically illustrating a configuration of a portion of a heater unit according to a comparative example.

### DETAILED DESCRIPTION

Hereinafter, the present embodiment will be described with reference to the accompanying drawings. For ease of understanding of the descriptions, in each drawing, the same components are denoted by the same reference signs as much as possible, and duplicate descriptions are not repeated.

A first embodiment will be described. An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W that is an object to be attracted is, for example, a silicon wafer. The electrostatic chuck 10 may be used in an apparatus other than the semiconductor manufacturing apparatus.

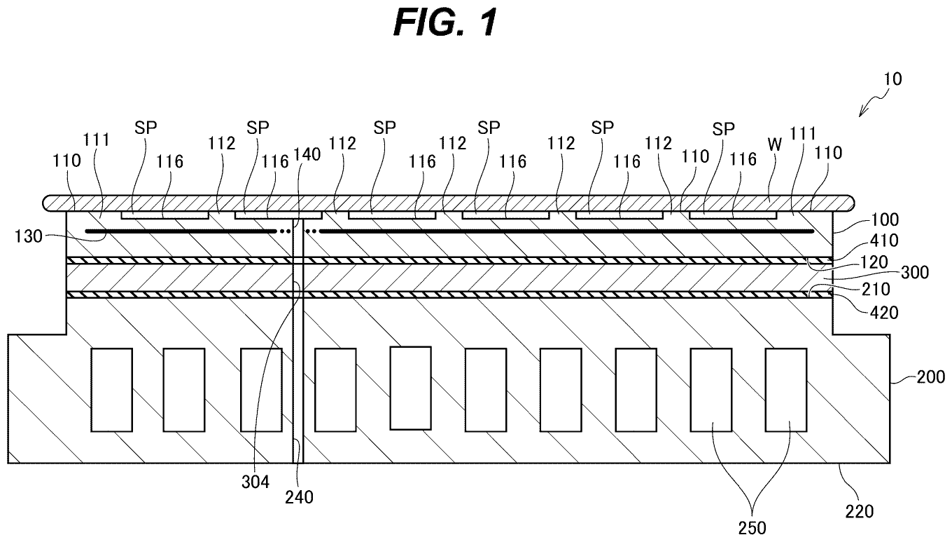

FIG. 1 is a cross-sectional view schematically illustrating a configuration of the electrostatic chuck 10 in a state in which the wafer W is attracted and held. The electrostatic chuck 10 includes a dielectric substrate 100, a base plate 200, and a heater unit 300.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a “placement surface” on which the wafer W is placed. A surface 120 on a lower side (that is, a side opposite to the placement surface) in FIG. 1 in the dielectric substrate 100 serves as a “surface to be joined” which is joined to the heater unit 300 through a joining layer 410. A perspective in a case where the electrostatic chuck 10 is viewed from the surface 110 side along a direction perpendicular to the surface 110 will also be hereinafter expressed as “top view”.

An attraction electrode 130 is embedded inside the dielectric substrate 100. The attraction electrode 130 is a thin planar (plate-like) layer made of a metallic material such as, for example, palladium, and is arranged so as to be parallel to the surface 110. As a material of the attraction electrode 130, molybdenum, platinum, tungsten, and the like may be used in addition to palladium. When a voltage is applied to the attraction electrode 130 from an outside via a feed line which is not illustrated in the drawing, an electrostatic force is generated between the surface 110 and the wafer W, and according to this, the wafer W is attracted and held. As a configuration of the above-described feed line, various publicly known configurations can be adopted. The single attraction electrode 130 may be provided as so-called a “monopolar” electrode as in the present embodiment, but may also include two attraction electrodes as so-called “bipolar” electrodes.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via a gas hole 140 which will be described later. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. An upper end of the seal ring 111 serves as a part of the surface 110 and abuts against the wafer W. It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the processing can be set to be close to uniformity.

A part denoted by reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. An upper end of each of the dots 112 becomes a part of the surface 110 and abuts against the wafer W. By providing the plurality of thus configured dots 112, warping of the wafer W is reduced.

The gas hole 140 is formed in the dielectric substrate 100. The gas hole 140 is a hole for supplying helium gas to the space SP, and is a circular through hole formed so as to extend vertically with respect to the surface 110. The gas hole 140 includes a plurality of gas holes 140, but FIG. 1 illustrates only one of the gas holes 140. Helium gas supplied from outside sequentially passes through a gas hole 240 formed in the base plate 200, which will be described later, and a through hole 304 formed in the heater unit 300, which will be described later, and is then supplied to the space SP through the gas hole 140.

For example, a porous body made of alumina or the like may be arranged inside the gas hole 140. With such a configuration, while flow of the gas in the gas hole 140 is secured, occurrence of insulation breakdown in a path through the gas hole 140 can be suppressed.

The base plate 200 is a substantially disk-shaped member that supports the dielectric substrate 100 and the heater unit 300. The base plate 200 is made of, for example, a metallic material such as aluminum. A surface 210 on the upper side in FIG. 1 in the base plate 200 serves as a “surface to be joined” which is joined to the heater unit 300 via a joining layer 420. The base plate 200 is joined to a surface on a side opposite to the dielectric substrate 100 side in the heater unit 300.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 250 are performed via openings which are not illustrated in the drawing and which are formed in a surface 220 opposite to the surface 210 in the base plate 200.

In the base plate 200, the gas hole 240 is formed at each position overlapped with the gas hole 140 in top view. The gas hole 240 is a circular through hole formed so as to vertically extend from the surface 210 toward the surface 220. A central axis of the gas hole 240 matches a central axis of the gas hole 140. As described above, the gas hole 140 serves as a part of the path for supplying helium gas to the space SP.

The gas hole 240 may be formed so as to extend entirely in a linear shape as in the present embodiment, or may be formed so as to bend on a way from the surface 210 toward the surface 220. The plurality of gas holes 240 on the surface 210 side may be aggregated into a small number of flow paths inside the base plate 200, and the flow paths may be extended to the surface 220 side.

For example, a porous body made of alumina or the like may be arranged inside the gas hole 240. With such a configuration, while flow of the gas in the gas hole 240 is secured, occurrence of insulation breakdown in a path through the gas hole 240 can be suppressed.

An insulating film may be formed on a surface of the base plate 200. As the insulating film, for example, an alumina film formed by thermal spraying can be used. When the surface of the base plate 200 is covered by the insulating film, it is possible to increase dielectric withstand voltage of the base plate 200.

The heater unit 300 generates heat by receiving power supplied from the outside, and heats the dielectric substrate 100. As described later, the heater unit 300 includes a plurality of heat generation portions 331 and the like, and a heating value at each heat generation portion 331 and the like can be individually regulated. By individually regulating the heating value at each component, the in-plane temperature distribution of the wafer W during processing can be made closer to uniform.

The heater unit 300 is sandwiched between the dielectric substrate 100 and the base plate 200, and joined to each of them. The heater unit 300 is joined to the dielectric substrate 100 via the joining layer 410, and the heater unit 300 is joined to the base plate 200 via the joining layer 420. Each of the joining layers 410 and 420 is a layer formed by curing a silicone adhesive, for example. In an inner part of each of the joining layers 410 and 420, a plurality of particulate fillers for enhancing thermal conductivity are arranged. As the filler, for example, particles containing alumina as a principal component can be used.

In the heater unit 300, the through hole 304 is formed at each position overlapped with the gas hole 140 in top view. The through hole 304 is a circular through-hole formed so as to extend in a direction vertical to the surface 110, and penetrates the whole heater unit 300. A central axis of the through hole 304 matches the central axis of the gas hole 140. As described above, the through hole 304 serves as a part of the path for supplying helium gas to the space SP.

In FIG. 1, a shape of the through hole 304 is illustrated in a simplified manner. An inner diameter of the through hole 304 is not entirely uniform in size, and has different sizes depending on a height position. The shape of the through hole 304 and the like will be described later.

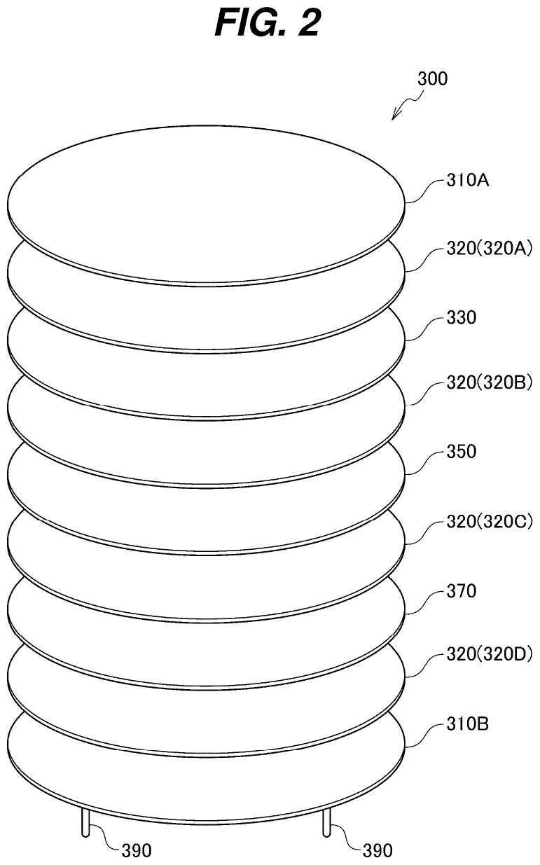

A specific configuration of the heater unit 300 will be described. FIG. 2 illustrates a configuration of the heater unit 300 as a schematic exploded view. As illustrated in FIG. 2, the heater unit 300 includes a first conductor plate 310A, a second conductor plate 310B, an insulating layer 320A, a sub-heater layer 330, an insulating layer 320B, a main heater layer 350, an insulating layer 320C, a bypass layer 370, an insulating layer 320D, and a power supply terminal 390. In the present embodiment, the sub-heater layer 330, the main heater layer 350, and the bypass layer 370 are arranged in the stated order from top in FIG. 2, but their arrangement order may be different from that in the present embodiment.

The first conductor plate 310A is a substantially disk-shaped member, and provided at an end part on an upper side in FIG. 2 in the heater unit 300. The first conductor plate 310A is a portion joined to the surface 120 of the dielectric substrate 100 via the joining layer 410.

The second conductor plate 310B is a substantially disk-shaped member, and provided at an end part on a lower side in FIG. 2 in the heater unit 300. The second conductor plate 310B is a portion joined to the surface 210 of the base plate 200 via the joining layer 420.

The first conductor plate 310A and the second conductor plate 310B are members for reinforcing the whole heater unit 300 by sandwiching the whole of the sub-heater layer 330, the main heater layer 350, the bypass layer 370, and the like therebetween. In the present embodiment, both of the first conductor plate 310A and the second conductor plate 310B are made of metal, but may be made of other materials having conductivity. The above-described through hole 304 is formed in each member, such as the first conductor plate 310A, constituting the heater unit 300, but illustration thereof is omitted in FIG. 2.

The insulating layer 320A is a layer provided between the first conductor plate 310A and the sub-heater layer 330 to electrically insulate therebetween. The insulating layer 320A also has a role of physically joining the first conductor plate 310A with the sub-heater layer 330. The insulating layer 320A is a polyimide film in the present embodiment, but may contain components other than polyimide, and may be made of a material different from polyimide.

The sub-heater layer 330 is a portion that generates heat by receiving power supplied from the outside. The sub-heater layer 330 corresponds to a “heat generation layer” in the present embodiment. In FIG. 2, the sub-heater layer 330 is schematically illustrated as a single disk, but the sub-heater layer 330 is actually divided into a plurality of regions, and each of the regions can be caused to individually generate heat. A specific configuration of the sub-heater layer 330 will be described later.

The insulating layer 320B is a layer provided between the sub-heater layer 330 and the main heater layer 350 to electrically insulate therebetween. The insulating layer 320B also has a role of physically joining the sub-heater layer 330 with the main heater layer 350. The insulating layer 320B is a polyimide film in the present embodiment, but may contain components other than polyimide, and may be made of a material different from polyimide.

The main heater layer 350 is a portion that generates heat by receiving power supplied from the outside. The main heater layer 350 corresponds to the “heat generation layer” in the present embodiment together with the sub-heater layer 330 described above. In FIG. 2, the main heater layer 350 is schematically illustrated as a single disk, but the main heater layer 350 is actually divided into a plurality of regions, and each of the regions can be caused to individually generate heat. A specific configuration of the main heater layer 350 will be described later.

A heating value per unit area of the main heater layer 350 is larger than that of the sub-heater layer 330 described above. The main heater layer 350 is used for raising a temperature of the whole dielectric substrate 100 in a short time. The sub-heater layer 330 is used for regulating a temperature of each component of the dielectric substrate 100, and making the in-plane temperature distribution of the wafer W approximately uniform. In this way, in the present embodiment, the two heater layers having respective roles are individually provided.

The insulating layer 320C is a layer provided between the main heater layer 350 and the bypass layer 370 to electrically insulate therebetween. The insulating layer 320C also has a role of physically joining the main heater layer 350 with the bypass layer 370. The insulating layer 320C is a polyimide film in the present embodiment, but may contain components other than polyimide, and may be made of a material different from polyimide.

The bypass layer 370 is a layer for electrically connecting the power supply terminal 390 to be described later with the sub-heater layer 330 and the main heater layer 350. In FIG. 2, the bypass layer 370 is schematically illustrated as a single disk, but the bypass layer 370 is actually divided into a plurality of parts. By providing the bypass layer 370 in a middle of an electric circuit connected to the sub-heater layer 330 and the like, it is possible to regulate a position of the power supply terminal 390 and the like. Each of the divided parts of the bypass layer 370 is partially electrically connected to the sub-heater layer 330 or the main heater layer 350.

The insulating layer 320D is a layer provided between the bypass layer 370 and the second conductor plate 310B to electrically insulate therebetween. The insulating layer 320D also has a role of physically joining the bypass layer 370 with the second conductor plate 310B. The insulating layer 320D is a polyimide film in the present embodiment, but may contain components other than polyimide, and may be made of a material different from polyimide.

At the time of manufacturing the heater unit 300, the respective layers illustrated in FIG. 2 are pressurized and heated as a whole in a laminated state. Due to this, the whole layers are joined and integrated with each other via the insulating layer 320A that is a polyimide film and the like.

When the above-described joining is completed, the insulating layer 320A, the insulating layer 320B, the insulating layer 320C, and the insulating layer 320D are joined to each other and integrated. The whole of the insulating layers integrated in this manner will also be hereinafter referred to as an “insulating layer 320”. The sub-heater layer 330 that is the heat generation layer, the main heater layer 350 that is the heat generation layer, and the bypass layer 370 are housed inside the insulating layer 320. The first conductor plate 310A is in contact with the insulating layer 320 from the dielectric substrate 100 side, and the second conductor plate 310B is in contact with the insulating layer 320 from a side opposite to the dielectric substrate 100.

The power supply terminal 390 is a portion that receives supply of power required for causing the sub-heater layer 330 and the like to generate heat from the outside. In the present embodiment, the power supply terminal 390 is formed as an elongated bar-shaped plug, and has one end part joined to the bypass layer 370. The power supply terminal 390 includes a plurality of power supply terminals 390 in accordance with the number of the bypass layers 370, only two of them are illustrated in FIG. 2. A non-illustrated through hole is formed at each position corresponding to the power supply terminal 390 in the base plate 200, and the power supply terminal 390 is inserted through the through hole.

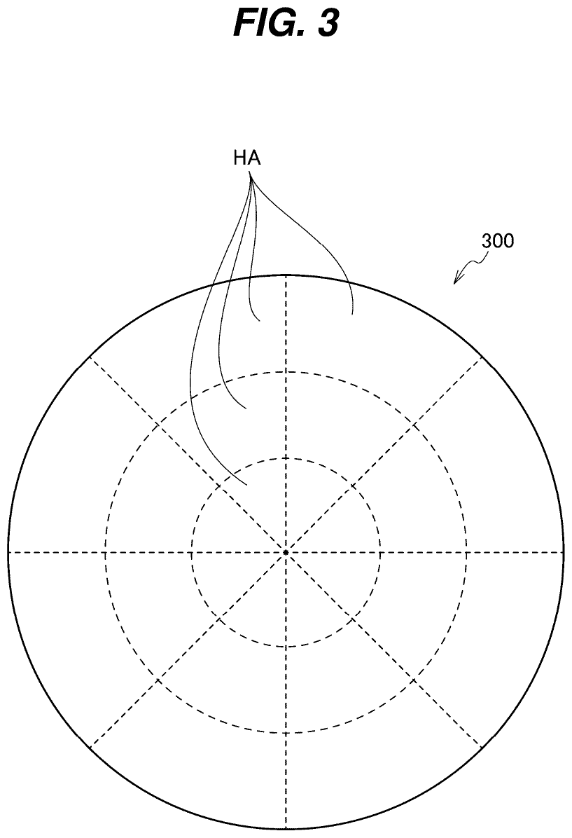

A configuration of the sub-heater layer 330 will be described. As described above, the sub-heater layer 330 is divided into the plurality of regions, and heat can be individually generated in each of the regions. FIG. 3 illustrates an example of a manner of dividing the sub-heater layer 330 in top view. In this example, the sub-heater layer 330 is divided into twenty-four regions HA in total.

The sub-heater layer 330 is configured as the linear heat generation portion 331, and individually routed in each of the regions HA. That is, twenty-four heat generation portions 331 in total are provided in the present embodiment.

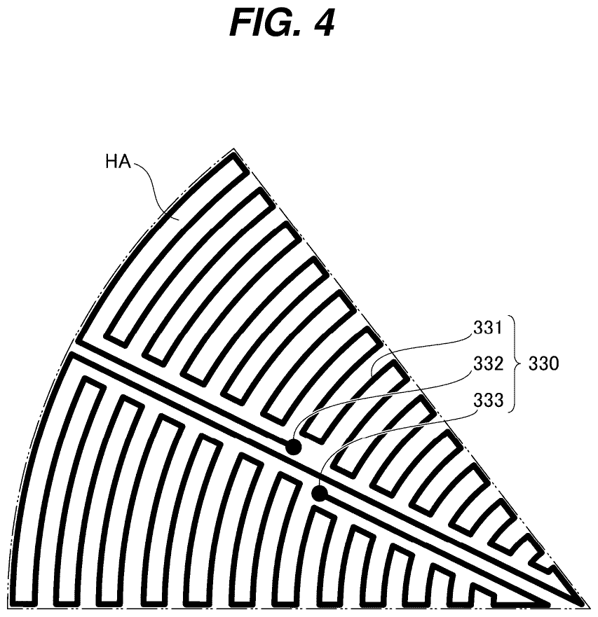

FIG. 4 illustrates an example of the heat generation portion 331 routed in one region HA. In each of the regions HA, the one linear heat generation portion 331 is routed along a path uniformly passing through substantially the entire range thereof. The heat generation portion 331 is a portion that generates heat by receiving power supplied from the outside. Although not illustrated, in a portion where the through hole 304 is formed, the heat generation portion 331 is routed along a path so as to avoid the through hole 304.

At both ends of the heat generation portion 331, circular pad parts 332 and 333 are respectively formed. The heat generation portion 331 and the pad parts 332 and 333 are formed by performing etching on thin metal foil, for example, and the whole thereof functions as one sub-heater layer 330. In other words, one sub-heater layer 330 is provided for each of the twenty-four regions HA in total.

A shape of the heat generation portion 331 illustrated in FIG. 4 is schematic, and is different from a real shape. The same applies to positions of the pad parts 332 and 333.

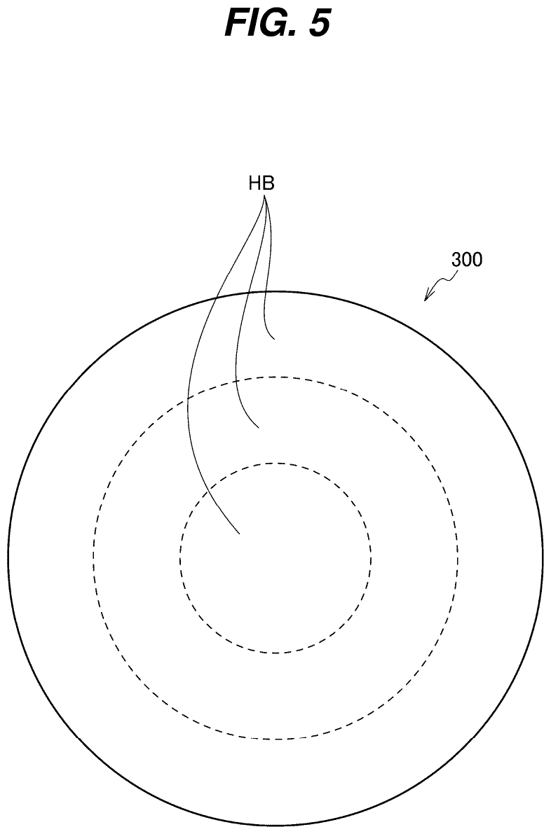

A configuration of the main heater layer 350 will be described. Similarly to the sub-heater layer 330, the main heater layer 350 is also divided into a plurality of regions, and each of the regions can be caused to individually generate heat. FIG. 5 illustrates an example of a manner of dividing the main heater layer 350 in top view. In this example, the main heater layer 350 is divided into three regions HB in total.

The main heater layer 350 is configured as a linear heat generation portion 351, and individually routed in each of the regions HB. That is, the three heat generation portions 351 in total are provided in the present embodiment.

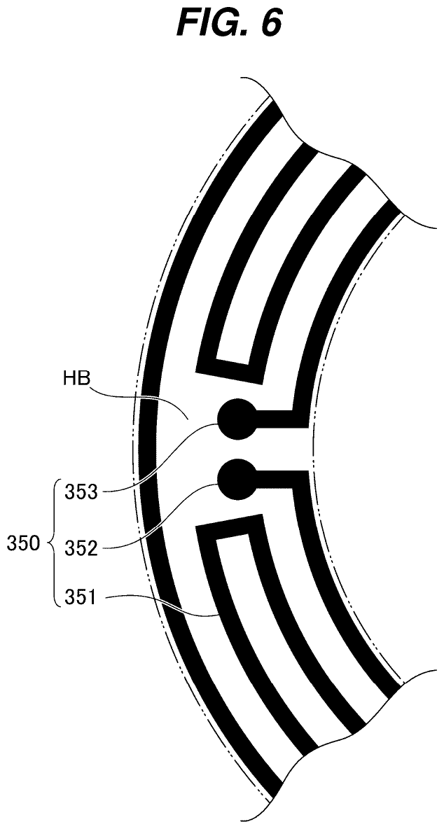

FIG. 6 illustrates an example of the heat generation portion 351 routed in one region HB. In each of the regions HB, the one linear heat generation portion 351 is routed along a path uniformly passing through substantially the entire range. The heat generation portion 351 is a portion that generates heat by receiving power supplied from the outside. Although not illustrated, in a portion where the through hole 304 is formed, the heat generation portion 351 is routed along a path so as to avoid the through hole 304. The number of the heat generation portions 351 (three in total) is less than the number of the heat generation portions 331 (twenty-four in total).

At both ends of the heat generation portion 351, circular pad parts 352 and 353 are respectively formed. The heat generation portion 351 and the pad parts 352 and 353 are formed by performing etching on thin metal foil, for example, and the whole thereof functions as one main heater layer 350. In other words, one main heater layer 350 is provided for each of the three regions HB in total.

A shape of the heat generation portion 351 illustrated in FIG. 6 is schematic, and is different from a real shape. The same applies to positions of the pad parts 352 and 353.

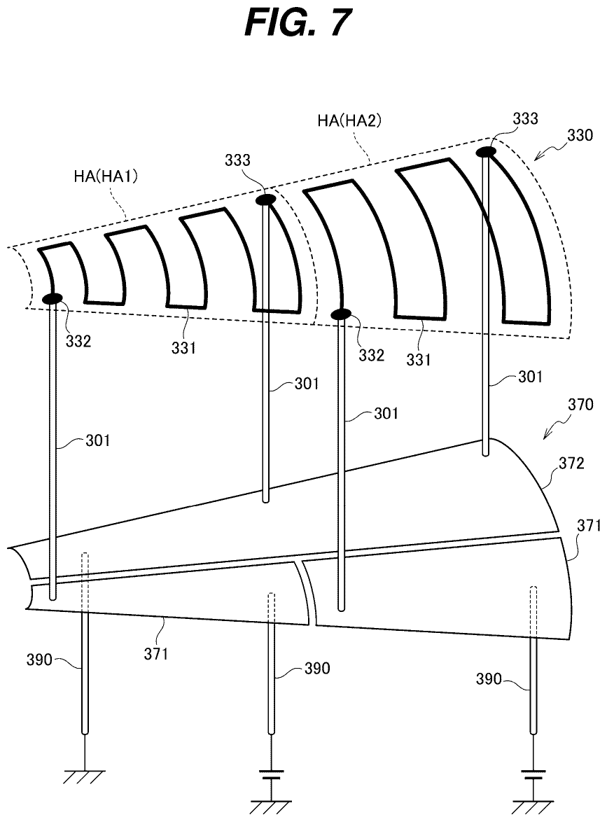

FIG. 7 illustrates a schematic perspective view of a configuration including two of the regions HA, the two sub-heater layers 330 arranged in them, the bypass layer 370 connected to the sub-heater layers 330, and the like. One of the two regions HA illustrated in FIG. 7 will also be hereinafter referred to as a “region HA1”. The other region HA will also be hereinafter referred to as a “region HA2”. Shapes of the heat generation portions 331 and the like illustrated in FIG. 7 are schematic, and are different from real shapes.

As described above, the bypass layer 370 is divided into the plurality of parts. FIG. 7 illustrates only three of the plurality of divided parts of the bypass layer 370. Each of the three divided parts of the bypass layer 370 denoted by reference sign “371” in FIG. 7 is arranged at a position overlapped with only one of the regions HA in top view. That is, it is individually arranged at a position immediately below each of the regions HA. A portion of the bypass layer 370 that is arranged as described above will also be hereinafter referred to as a “bypass layer 371”.

Each of the divided parts of the bypass layer 370 denoted by reference sign “372” in FIG. 7 is arranged at a position overlapped with both of the region HA1 and the region HA2 in top view. A portion of the bypass layer 370 that is arranged as described above will also be hereinafter referred to as a “bypass layer 372”.

In the sub-heater layer 330 arranged in the region HA1, the pad part 332 at one end of the heat generation portion 331 is electrically connected to the bypass layer 371 immediately below the pad part 332. The pad part 333 at the other end of the heat generation portion 331 is electrically connected to the bypass layer 372.

Similarly to the above, in the sub-heater layer 330 arranged in the region HA2, the pad part 332 at one end of the heat generation portion 331 is electrically connected to the bypass layer 371 immediately below the pad part 332. The pad part 333 at the other end of the heat generation portion 331 is electrically connected to the bypass layer 372.

The electrical connection between the respective parts as described above are implemented by welding upper and lower layers to each other, for example. For ease of understanding of the configuration, in FIG. 7, each welding part is schematically illustrated as a stick-shaped member extending in a straight line (a portion denoted by reference sign 301). At a portion overlapped with each welding part in top view, an opening is formed in each of layers (the insulating layer 320B, the main heater layer 350, and the insulating layer 320C) between the sub-heater layer 330 and the bypass layer 370, and the sub-heater layer 330 and the bypass layer 370 are directly connected through the opening.

The sub-heater layer 330 and the bypass layer 370 may be electrically connected by welding as in the present embodiment, but may be electrically connected by using another method. For example, they may be electrically connected via a conductive member extending in an upper and lower direction. In any configuration, the sub-heater layer 330 and the bypass layer 370 are connected via an electric circuit denoted by reference sign 301 in FIG. 7. The electric circuit will also be hereinafter referred to as a “connection part 301”.

One end of the power supply terminal 390 is joined to each of the bypass layers 371 from the lower side in FIG. 7. A voltage is individually applied to each of the power supply terminals 390 from an external DC power supply. One end of the power supply terminal 390 is also joined to the bypass layer 372 from the lower side in FIG. 7. The power supply terminal 390 is grounded.

As described above, in each of the sub-heater layers 330 provided for each of the regions HA, the one pad part 332 is connected to the individual DC power supply via the bypass layer 371, and the other pad part 333 is grounded via the common bypass layer 372. The other sub-heater layers 330 not illustrated in FIG. 7 are also connected to the DC power supply and the like with the same configuration. With such a configuration, it is possible to individually supply power to each of the plurality of sub-heater layers 330, and regulate a heating value at each part.

It is also possible to supply power directly from the power supply terminal 390 without using the bypass layer 370 to the sub-heater layer 330. However, with the configuration of supplying power via the bypass layer 370 as in the present embodiment, a degree of freedom in arrangement of the power supply terminal 390 can be enhanced, or the power supply terminals 390 to be grounded can be integrated into one terminal.

Power supply to each of the main heater layers 350 is implemented by the same configuration as described above. Its specific configuration is the same as in FIG. 7, and thus description and illustration thereof are omitted.

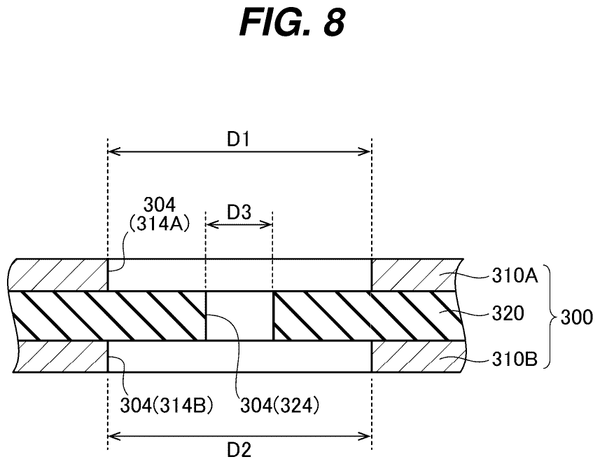

A configuration of the vicinity of a portion where the through hole 304 is formed in the heater unit 300 will be described. FIG. 8 is a schematic cross-sectional view illustrating a part of a section of the heater unit 300 taken along a plane passing through the central axis of the through hole 304. In FIG. 8, the entire insulating layer 320 is illustrated as a single block, and illustrations of the heat generation portion 331, the heat generation portion 351, and the like housed inside the insulating layer 320 are omitted. The heat generation portion 331 and the heat generation portion 351 are routed along a path so as to avoid the through hole 304 in top view. Accordingly, the heat generation portion 331 and the heat generation portion 351 are not exposed on an inner surface of the through hole 304.

A portion of the through hole 304 that is formed in the first conductor plate 310A will also be hereinafter referred to as a “through hole 314A”. A portion of the through hole 304 that is formed in the insulating layer 320 will also be hereinafter referred to as a “through hole 324”. A portion of the through hole 304 that is formed in the second conductor plate 310B will also be hereinafter referred to as a “through hole 314B”.

As described above, the inner diameter of the through hole 304 is not entirely uniform in size. As illustrated in FIG. 8, a diameter D2 of the through hole 304 (through hole 314B) formed in the second conductor plate 310B is larger than a diameter D3 of the through hole 304 (through hole 324) formed in the insulating layer 320. Similarly, a diameter D1 of the through hole 304 (through hole 314A) formed in the first conductor plate 310A is larger than the diameter D3 of the through hole 304 (through hole 324) formed in the insulating layer 320.

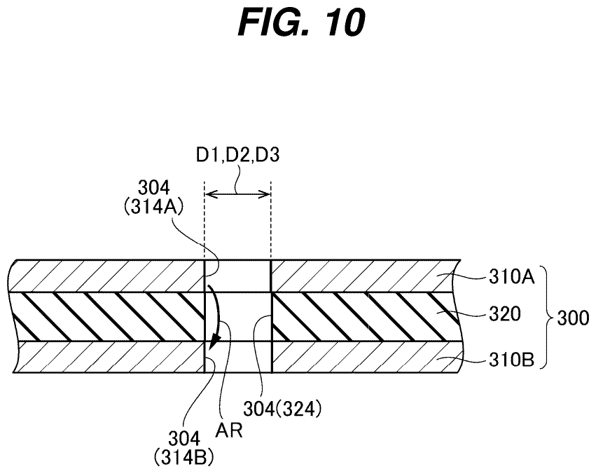

In order to clarify a reason for adopting such a configuration, a configuration of the electrostatic chuck 10 according to a comparative example will be described. In the configuration of the comparative example illustrated in FIG. 10, the inner diameter of the through hole 304 is entirely uniform in size. In other words, the diameter D1 of the through hole 314A, the diameter D2 of the through hole 314B, and the diameter D3 of the through hole 324 are equal to one another.

When the wafer W is being processed in the semiconductor manufacturing apparatus, the wafer W and the electrostatic chuck 10 are exposed to plasma. Due to influence of the plasma, a potential difference may occur between the first conductor plate 310A and the second conductor plate 310B. When the potential difference becomes large, insulation breakdown occurs inside the through hole 304 along a path that extends from the first conductor plate 310A to the second conductor plate 310B. Specifically, insulation breakdown occurs along a path indicated by arrow AR, extending from an edge portion of the through hole 314A in the first conductor plate 310A to an edge portion of the through hole 314B in the second conductor plate 310B.

Thus, in the electrostatic chuck 10 according to the present embodiment, in order to suppress occurrence of insulation breakdown along such a path, the diameter D2 of the through hole 314B is set to be larger than the diameter D3 of the through hole 324. As illustrated in FIG. 8, in a configuration with D2>D1 as in the present embodiment, a portion of the insulating layer 320 projects so as to obstruct, in the middle, a path that extends from the edge portion of the through hole 314A in the first conductor plate 310A to the edge portion of the through hole 314B in the second conductor plate 310B. Inside the through hole 304, insulation breakdown from the first conductor plate 310A to the second conductor plate 310B can occur only along a path that greatly bypasses the projecting insulating layer 320, and thus occurrence of insulation breakdown as illustrated FIG. 10 can be suppressed.

In the heater unit 300, for example, through holes for inserting lift pins are formed at positions different from a position directly below the gas hole 140. The configuration of the through hole 304 and its vicinity as illustrated in FIG. 8 can also be adopted in other through holes formed in the heater unit 300 and their vicinity.

A second embodiment will be described. Hereinafter, an aspect different from the first embodiment will be mainly described, and descriptions on an aspect common to the first embodiment are omitted as appropriate.

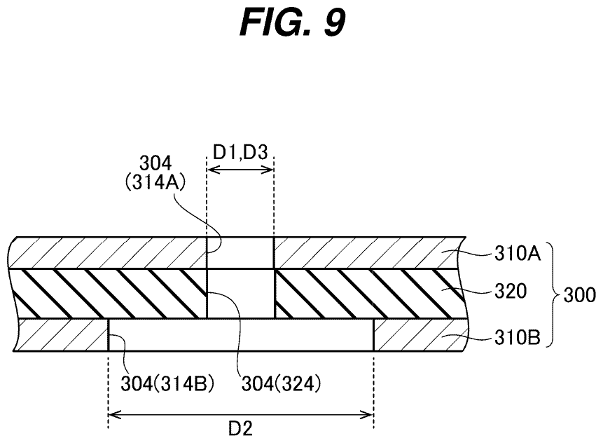

FIG. 9 schematically illustrates part of the configuration of the heater unit 300 according to the present embodiment as a cross-sectional view similar to FIG. 8. As illustrated in FIG. 9, in the present embodiment as well, the diameter D2 of the through hole 304 (through hole 314B) formed in the second conductor plate 310B is larger than the diameter D3 of the through hole 304 (the through hole 324) formed in the insulating layer 320. Moreover, in the present embodiment, the diameter D1 of the through hole 304 (the through hole 314A) formed in the first conductor plate 310A is smaller than the diameter D2 of the through hole 304 (through hole 314B) formed in the second conductor plate 310B, and is equal to the diameter D3 of the through hole 304 (the through hole 324) formed in the insulating layer 320.

The first conductor plate 310A is a portion joined to the dielectric substrate 100. When the diameter D1 of the through hole 314A formed in the first conductor plate 310A is too large, a heat transfer path between the heater unit 300 and the dielectric substrate 100 is narrowed by an amount corresponding to the through hole 314A. As a result, the temperature of the wafer W may locally increase or decrease at a position directly above the through hole 304. In order to suppress such temperature variation, it is preferable, as in the present embodiment, to reduce the diameter D1 of the through hole 314A formed in the first conductor plate 310A, and to sufficiently secure the heat transfer path between the heater unit 300 and the dielectric substrate 100.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be attracted is placed; and
a heater unit that is joined to the dielectric substrate and heats the dielectric substrate, wherein
the heater unit includes
a heat generation layer that generates heat by receiving electric power supplied from outside,
an insulating layer that houses the heat generation layer inside,
a first conductor plate that is arranged so as to be in contact with the insulating layer from the dielectric substrate side, and
a second conductor plate that is arranged so as to be in contact with the insulating layer from a side opposite to the dielectric substrate,
a through hole that penetrates the entire heater unit in a direction vertical to the placement surface is formed in the heater unit, and
a diameter of the through hole formed in the second conductor plate is larger than a diameter of the through hole formed in the insulating layer.

2. The electrostatic chuck according to claim 1, wherein a diameter of the through hole formed in the first conductor plate is smaller than the diameter of the through hole formed in the second conductor plate.

3. The electrostatic chuck according to claim 2, wherein the diameter of the through hole formed in the first conductor plate is equal to the diameter of the through hole formed in the insulating layer.
